(19) United States
(12) Patent Application Publication
(10) Pub. No.: US 2009/0199892 A1
(43) Pub. Date: Aug. 13, 2009

(54) Solar earth module

(76) Inventor: Roger A. Farquhar, Hoppers Crossing (AU)

Correspondence Address: HARNESS, DICKEY & PIERCE, P.L.C., P.O. BOX 828, BLOOMFIELD HILLS, MI, 48303, US

(21) Appl. No.: 11/921,282

(22) PCT Filed: May 31, 2006
(86) PCT No.: PCT/AU2006/000737

§ 371 Date: Nov. 29, 2007

(30) Foreign Application Priority Data
May 31, 2005 (AU) 2005902812
Dec. 9, 2005 (AU) 2005906948

(51) Int. Cl. H01L 31/058; F24J 2/04; F24J 2/10; E04D 13/18; B23P 15/26; F25B 37/00; F25B 27/00; E04B 1/70

(52) U.S. Cl. 136/248; 126/634; 126/692; 126/621; 29/726; 62/271; 62/235.1; 126/633; 52/173.3; 52/302.1

(57) ABSTRACT

A solar collector system (10, 30, 82, 82′, 171) includes a photovoltaic means (24, 174) for conversion of solar energy into electrical energy and a pathway/conduit (22, 94, 94′, 94″) for thermal transfer fluid which is in thermal communication with the photovoltaic means (24, 174). A shaped solar concentrator surface (12, 58, 58′, 173) may have at least one focus and the pathway/conduit (22, 94, 94′, 94″) may be disposed at the focus. The shaped solar concentrator surface (12, 58, 58′, 173) may be comprised of roof cladding material (58′) which is integrally formed to support the conduit (94) at the focus. Alternatively, the concentrator surface (173) may be disposed in a trough of corrugated roof cladding, with a transparent or translucent cover (98) over the top. The covers may be domed covers having an axis of curvature which substantially aligns with the roof gradient. A roofing structure comprises intersecting first (48) and second (50) roofing planes. The first roofing plane (48) extends beyond the intersection to define an extended roofing plane (54) with a cavity therebeneath housing one or more components (10, 30) of a solar collector assembly. In a particular ceiling construction, a sheeting product (112) is installed with a network (115) for liquid dispersal onto the upper surface of the sheeting product (112). The construction provides for evaporative airflow over the upper surface of the sheeting product. The solar collector may be arranged for use in a cooling/heating system based on an absorption refrigeration system.

### FIELD OF THE INVENTION

The present invention relates to the field of energy storage. In particular, although not exclusively, the invention relates to harnessing of solar energy and most particularly to solar collectors. However, the invention also relates to various aspects of building construction to aid in dispersal of stored energy and for maintaining a desirable ambient temperature within a building. While the invention has been described in connection with residential building construction, it will be appreciated that the concepts can be easily transported into any commercial setting.

### BACKGROUND TO THE INVENTION

Governments worldwide are continually seeking to address energy issues which range from depletion of fossil fuels and pollution of the earth's atmosphere. Research has ascertained that around 12% of total energy usage is in domestic dwellings and 75% of that energy is used to heat water and space. Accordingly, if energy efficient solutions could be found for the heating of water and space then some impact could be made on the global energy crisis.

It is therefore an object of the present invention to provide energy related solutions which address or at least ameliorate this growing issue.

### SUMMARY OF THE INVENTION

In accordance with a first aspect of the present invention there is provided a solar collector comprising: a shaped solar concentrator surface having at least one focus; and a solar energy converter disposed at the focus of the shaped collector, wherein the solar energy converter is in the form of a vessel for thermal transfer fluid with a series of photovoltaic cells provided on the surface of the vessel.

The shaped concentrator surface may have one or more foci depending upon the shape. The concentrator surface may be curved and possible curved surfaces include spherical, parabolic, elliptical or parts thereof. There could be a plurality of surface portions which are joined to form a compound surface. These surface portions may each have a focus. Alternatively, the surface portions may have common foci.

In a preferred form of the invention, the concentrator surface is elongate with a uniform cross section along its length. This is may give rise to a linear focus along which the solar energy converter may be disposed. In a most preferred form of the invention, the uniform cross section is a compound surface with each of the portions of the compound surface having substantially aligned or common foci. In a preferred form of the invention, the uniform cross section is a compound parabolic surface of two substantially parabolic surface portions intersecting along a line of symmetry of the concentrator surface. The intersection of the two parabolic surface portions may be at or adjacent to the linear focus with the solar energy converter supported by the structure of the shaped concentrator surface.

Preferably the surface of the shaped concentrator surface is reflective and may be constructed from metal or plastic. A coating applied to the structure may provide the specular properties. This assembly may be disposed within a housing which is preferably glass topped. The solar collector is preferably mounted in a disposition to capture sunlight.

The thermal transfer fluid may be circulated through the converter and a reservoir of fluid may be provided within a storage vessel. The storage vessel may also serve as a thermal storage device to store the heat from the circulated fluid. Accordingly, the heat from the circulated fluid may be transferred to a thermal storage medium. In a preferred form of the invention, the thermal storage medium comprises a calcium chloride solution. An effective heat transfer arrangement may be disposed within the thermal storage vessel for transfer of heat from the circulating liquid to the thermal transfer medium.

The solar energy converter includes both solar to electrical conversion as well as thermal conversion discussed above. For example, a hollow vessel may be disposed at the focus of the solar collector with photovoltaic means disposed on the exterior with liquid circulating through the hollow interior. An effective form of converter for the preferred linear solar concentrator with a compound concentrator surface of two intersecting parabolas may comprise an elongate conduit of uniform triangular cross-section with photovoltaic means provided on each of the three sides with two of the sides of the triangular cross-section oriented towards a respective parabolic surface portion.

Alternatively, the photovoltaic means may specifically employ Sliver™ cells which are ultra thin mono-crystalline cells less than 70 microns thick which are micro-machined from mono-crystalline silicone. These may be arranged in spaced disposition on a pipe which extends at the focus at the solar concentrator. Accordingly, the pipe may still be heated by the solar energy while the photovoltaic cells are used to create electricity. The pipe may be transparent to permit sunlight to still permeate through the cells through to the pipe. Furthermore, the Sliver cells may be positioned on a transparent coating overlaying a reflective surface on the pipe. With the Sliver cells spaced, their bifacial characteristic may be utilised to reduce the surface area required of the photovoltaic cells.

In another preferred form of the invention, the pipe at the focus of the solar concentrator may be transparent or at least translucent to thereby provide an ultraviolet disinfection unit within a solar collector assembly.

In accordance with a second aspect of the present invention there is provided a solar collector comprising: a photovoltaic means for conversion of solar energy into electrical energy; and a pathway for thermal transfer fluid which is in thermal communication with the photovoltaic means.

The pathway may comprise a conduit for the flow of the thermal transfer fluid. In this regard, the features described above in connection with the circulating liquid, and the thermal storage vessel may be applied to the second aspect of the invention. Furthermore, the solar collector according to the second aspect of the invention may be used in connection with a solar concentrator as described above.

In accordance with a third aspect of the present invention there is provided a roofing structure comprising: a first roofing plane supporting roof cladding material; a second roofing plane supporting roof cladding material with said first and second planes intersecting and wherein said first roofing plane extends beyond the intersection to define an extended roofing plane with a cavity therebeneath housing one or more components of a solar collector assembly.

The solar collector may be of the type disclosed above in connection with the first and second aspects of the invention.

As set out in the third aspect of the invention, there are first and second intersecting planes. These planes may be arranged at inclined angles to define a pitched roof as found in traditional housing. The intersection of the roofing planes may be a theoretical intersection. Alternatively there may be an intersection of actual structural components. For example, the first and second roofing planes may be supported by intersecting beams or spaced trusses may make up the roofing structure with the two top chords of the trusses supporting the first and second roofing planes. As in conventional roofing structures, the intersecting beams or spaced trusses may be transversely joined by purlins. However, other constructions are possible within the scope of the present invention.

The extended roofing plane may be supported by extension of one of the chords of a truss structure or by an extension of the beams on one side of a roof structure comprised of intersecting beams. Alternatively, the extended roofing plane may be supported by a supplementary beam joined to the beams or chords supporting the first roofing plane. This is particularly appropriate to a retrofitted construction. The extended roofing plane is preferably extended to a length such that the angle of the transparent cover and/or solar collector is at an optimum angle for collection of the sun's rays.

A transparent cover may be provided. It may be comprised of glass or plastics materials such as Perspex. The transparent cover may form part of the solar collector unit. The cover may incorporate Fresnel lenses to improve the angle of solar acceptance.

The extended roofing plane may optionally include a ventilation hatch for the release of trapped heated air from within the cavity or within the roof space.

The solar collector assembly may form part of a space heating or cooling assembly.

In accordance with a fourth aspect of the present invention there is provided a method of retrofitting one or more components of a solar collector assembly into a pitched roof structure comprised of first and second intersecting roofing planes supporting roof cladding material, said method including:

extending the first roofing plane beyond the point of intersection to define an extended roofing plane with a cavity therebeneath; and

installing a one or more components of the solar collector assembly within the cavity.

The method may further include removing cladding material from the second roofing plane.

In accordance with a fifth aspect of the present invention there is provided a solar collector assembly comprising:

a reflector portion; and

a vessel disposed to receive reflected solar radiation from the reflector portion;

wherein the reflector portion provides an integrally formed mount for supporting the vessel.

Preferably, the vessel is a conduit such as a pipe. Preferably, the cover is in the form of an elongate dome with the convex side facing upwardly. The dome may be sized to house a plurality of pipes side by side.

The covers may have shaped longitudinal edges which are complimentary with the shape of the reflector portion to seal against moisture, dust and vermin. Furthermore, the covers may also incorporate condensation collection channels for collection and removal of moisture. Furthermore, the assembly may be provided with ends which close the opposite ends of the assembly. The ends may be of a shape complimentary to the roof cladding material.

The conduit or the internal pipe may be connected to a thermal storage device as described as above in connection with the first aspect of the invention. Water may be circulated through pipes located within the thermal storage medium to provide heat to the thermal storage medium for subsequent distribution to domestic appliances such as wall hung radiators through a network of water pipes. Alternatively, the fluid within the internal pipe or conduit may be the circulated fluid to the domestic appliances.

Other specially adapted household items or appliances may be used as heat transfer devices, for example, flooring, wall and skirting panels could encase thermal storage medium and could be connected to the network of heated water pipes. Alternatively, the network of heated water pipes could be housed in flooring underlay. Likewise, a ceiling fan could be adapted as a heat transfer device. For example, the mounting base of the ceiling fan could be provided with a receptacle containing a thermal storage medium to thereby transfer heat to the room.

The solar collector assembly could also form part of a cooling system and accordingly could convey refrigerant used in such a cooling system. In another embodiment, the conduit may be of clear plastic tubing for the passage of water, enabling the solar collector assembly to function as an ultraviolet decontamination device. Thus the solar collector assembly may be multifunctional.

The unitary sheet forming the reflector portion may be metal sheeting formed by extrusion or rolling. Alternatively, the unitary sheet may be of plastic sheeting which is molded or extruded. The sheet may be coated to provide a specular surface.

In accordance with a sixth aspect of the present invention there is provided a solar collector assembly comprising:

a first reflector portion shaped to be received in a trough of corrugated roof cladding;

a conduit portion disposed to receive solar radiation from the first reflector portion; and

a cover extending over the first reflector portion and the conduit portion.

In a preferred form of this invention, a second reflector portion is also provided which is arranged to be received in an adjacent trough of the corrugated roof cladding. The second reflector portion may be integrally formed with the first reflector portion. The reflector portions may be in the form of a rolled sheet. Alternatively, the reflector portions may be in the form of molded or extruded plastic sheeting with desirably a reflective coating provided on the upper surface thereof. In this form of the invention, it is preferred that the cover extends over both of the reflector portions to form a solar collector assembly.

The solar collector assembly may be sold in a kit formed with commensurate lengths of the cover and internal piping. Any of the features described above in connection with the first and fifth aspects of the invention may be applied to this aspect of the invention.

In accordance with a seventh aspect of the present invention there is provided a solar collector assembly comprising:

a first reflector portion; and

an internal conduit portion disposed to receive reflected solar radiation from the reflector portion, wherein the internal conduit portion is transparent or at least translucent.

The seventh aspect of the invention may incorporate any of the features set out in the fifth and sixth aspects of the invention. The conduit portion is intended to convey water. The reflector portion may act to concentrate sunlight onto the transparent conduit, enabling UV radiation to pass through the water, thereby disinfecting the water. The holding times of water within the conduit may be controlled to ensure satisfactory disinfection, depending upon the intensity of ultraviolet radiation.

In accordance with an eighth aspect of the present invention there is provided a roofing construction for a sloping or pitched roof, the roofing construction including solar collectors which incorporate one or more transparent or translucent domed covers, the domed covers having an axis of curvature which substantially aligns with the roof gradient.

In a most preferred form of the invention, the covers are evenly spaced on the roof. Furthermore, they may extend substantially the distance between the ridge and the eaves. This presents aesthetic roof construction incorporating solar collectors. In a most preferred form, the covers may be shaped so as to have a stepped outer surface so that when installed they have an overlap appearance in the manner of roof tiles further enhancing the aesthetics. Additionally, or alternatively, the covers may be overlapped at their end edges in the manner of roof tiles, where a single cover is insufficient to extend the desired length.

In a preferred form of the invention, the covers may be used in conjunction with corrugated roofing. For example, the covers may span transversely across two troughs of the corrugated roofing with the solar collector housed within the two troughs as has been described above.

The covers may provide a mounting for conduits of the solar collectors. The conduits may be integrally formed with the covers.

In accordance with a ninth aspect of the invention there is provided a building construction including:

a sheeting product installed in a ceiling or a sub-roof space;

a network for liquid dispersal onto the upper surface of the sheeting product, wherein the construction provides for evaporative airflow over the upper surface of the sheeting product.

The sheeting product may incorporate integral recesses to house pipes that form a network for liquid dispersal. Furthermore, the sheeting product may be shaped so as to present recesses or troughs for collecting of the liquid therein for subsequent evaporation. Furthermore, the sheeting product may be laminated with absorbent material for improved dispersion of the liquid. In a preferred form of the invention, the sheeting product is shaped to increase the surface area and accordingly the evaporative surface area thereby increasing the heat transfer capabilities thereof.

The construction may provide for an airflow path along the sheeting product to be vented externally of the building construction. Furthermore, where the building construction incorporates a solar collector, the airflow path may pass along the underside of the solar collector. For this purpose, a passage may be provided between a layer of insulative sheeting attached to the underside of the top chord of a roof truss of the building construction and the roof cladding. Furthermore, one or more fans may be provided to assist in creating the evaporative airflow.

Preferably, the sheeting product is arranged with an incline towards the periphery of the building construction for collection of the liquid in a storage chamber which may be located externally of the building construction. To facilitate the sheeting product extending on an incline, the bottom chord of the truss to which the sheeting product is attached may present an appropriate incline. Alternatively, spacers may be inserted to facilitate the incline.

In accordance with the tenth aspect of the present invention, there is provided a ceiling construction including:

a sheeting product having one or more recesses defined therein to house thermal transfer pipes; and

one or more covers to extend across the respective recesses.

The recesses may extend longitudinally within the sheeting product and may be shaped to enhance thermal transfer capabilities. Preferably, the sheeting product is of uniform cross-section with the recesses extending longitudinally within the sheeting product.

In accordance with an eleventh aspect of the present invention there is provided an assembly for a ceiling within a room or space, the assembly including:

a sheeting product including a shaped portion to increase the surface area and hence the heat transfer capabilities thereof and one or more planar portions adjacent to the shaped portion;

cooling and/or heating components disposed on or adjacent the sheeting product; and

a cover portion to extend across the shaped portion to present, towards the room, a substantially planar ceiling surface.

The tenth and eleventh aspects of the invention may incorporate any of the features described above in connection with the ninth aspect of the invention.

In accordance with a twelfth aspect of the present invention there is provided a solar cooling system comprising:

a solar collector to heat a liquid passing therethrough by solar radiation;

means for circulating a solution of an evaporable refrigerant in a less evaporable solvent through said solar collector; and

an absorption refrigeration system, wherein the solar collector serves as a vapour generator of said system, the system further including a vapour liquid separator connected to an outlet of said solar collector, a condenser for condensation of a heated vapour of said refrigerant, an expansion valve through which the condensed refrigerant is introduced into an indoor evaporator to take latent heat from the air in the room during the evaporation process and an absorber in which the cooled refrigerant is absorbed in said solvent, wherein the solar collector is arranged on a roof surface, the subspace of the roof surface being vented to enhance air flow underneath the solar collector, and wherein said condenser and/or the absorber is arranged to be cooled by the vented air flow.

The solar collector may have the form as set out in any of the first, second, fifth and sixth aspects of the invention above. The solar collector may be mounted on a roof construction as set out in the fourth, fifth and eighth aspects of the invention. Furthermore, the invention, could also be utilised in conjunction with the constructions of the ninth, tenth and eleventh aspects of the invention. In particular, the pipes of the evaporator or indoor heat exchanger may be incorporated into the ceiling. The separator and the condenser could also be located in the cavity formed by the extended roofing plane as described in the third and fourth aspects of the invention.

Any suitable refrigerant may be used in the system such as a combination of water, ammonia and hydrogen gas to create a continuous cycle for the ammonia which acts as the coolant. Any other known refrigerant systems may be used. Preferably, the absorber is disposed in the eaves of the building construction in the region of an air intake vent. The condenser may be disposed in the region of an air outlet vent. The air flow created underneath the solar collector is known as anabatic flow.

In a preferred form of the invention, the solar cooling system may be operable in reverse cycle by allowing the refrigerant vapour to by pass the condenser and evaporator and direct the hot gas through an indoor heat exchanger. The vent may be selectively closable when operating in the heating mode. Additionally, air within the subspace may be circulated to the living space.

In accordance with a thirteenth aspect of the invention, there is provided a solar heating/cooling system for heating or cooling a building space comprising:

a solar collector adapted to heat a solution of an evaporable refrigerant in a less evaporable solvent through said solar collector;
a heating/cooling regime selection means for selective operation of the system for either a heating or cooling mode;
an absorption refrigeration system operable on selection of cooling mode, wherein the solar collector serves as a vapour generator of said system, the system further including a vapour liquid separator connected to an outlet of said solar collector, a condenser for condensation of a heated vapour of said refrigerant, an expansion valve through which the condensed refrigerant is introduced into an indoor heat exchanger for heat exchange between the refrigerant and air and an absorber in which the cooled refrigerant is absorbed in said solvent; and
a thermal storage and dispersal system operable on selection of heating mode, wherein the thermal storage and dispersal system includes a thermal storage vessel operable for circulation of the heated refrigerant therethrough for subsequent dispersion of the heat to the building space.

This invention may also be said broadly to consist in the parts, elements and features referred to or indicated in the specification of the application, individually or collectively, and any or all combinations of any two or more of said parts, elements or features, and where specific integers are mentioned herein which have known equivalents in the art to which this invention relates, such known equivalents are deemed to be incorporated herein as if individually set forth.

The invention consists in the foregoing and also envisages constructions of which the following gives examples.

As used herein, the term “comprise” and variations of the term, such as “comprising”, “comprises” and “comprised”, are not intended to exclude other additives, components, integers or steps.

### BRIEF DESCRIPTION OF THE DRAWINGS

In order that the invention may be fully understood, one embodiment will now be described by way of example with reference to the drawings in which:

FIG. 1b is a plan view of a solar collector in accordance with a preferred embodiment of the present invention;

FIG. 1a is a transverse cross-section through the collector of FIG. 1b);

FIG. 1c is a longitudinal side view of the collector of FIG. 1b);

FIG. 1d is a transverse cross-sectional view like FIG. 1a) except showing a modified energy converter;

FIG. 1e is a transverse cross-sectional view like FIG. 1a) showing another modified energy converter;

FIG. 2 is a diagrammatic view of a solar collector assembly in accordance with a preferred embodiment of the present invention employing three solar collectors as shown in FIG. 1;

FIGS. 3a to 3d are various heat exchanger devices;

FIG. 4 is a section through an apex of a roof structure in accordance with a preferred embodiment of the present invention;

FIG. 5 is a section through an apex of a roof structure similar to FIG. 4;

FIG. 6 is a detail of a ceiling structure of FIG. 5;

FIG. 7a) is a perspective view of insulative sheeting used in the roof construction of FIG. 5;

FIG. 7b) is a section through the roof structure showing how the insulative sheeting is installed

FIG. 8 is an end view of a modified form of transparent cover for assembly with a modified form of solar collector assembly shown in FIG. 11;

FIG. 9 is a side view of the transparent cover shown in FIG. 8;

FIG. 10 is an end sectional view of components of the solar collector assembly shown in FIG. 11;

FIG. 11 is an assembled end view of a modified form of solar collector assembly;

FIG. 12 is an end view of yet another modified form of solar collector assembly;

FIG. 13 is an end view in exploded form illustrating some components form the solar collector assembly illustrated in FIG. 12;

FIG. 14 is a section through an apex of a roof structure similar to FIG. 4, except illustrating the use of the solar collector assembly illustrated in FIG. 11;

FIG. 15 is an exploded view of a thermal ceiling construction;

FIG. 16 is an assembled view of the thermal ceiling construction of FIG. 19;

FIG. 17 is a perspective view of a portion of the ceiling and roof construction at the eaves of a building;

FIG. 18 is an exploded end view of a solar collector assembly including modified roof cladding of FIGS. 12 and 13;

FIG. 19 is a plan view of a solar collection unit for housing “Sliver” cells;

FIG. 20 is a sectional view through the solar collection unit of FIG. 19;

FIG. 21 is a sectional view through yet another form of solar collector assembly;

FIG. 22 is a sectional view still through still another form of solar collector assembly; and

FIG. 23 is a plan view of a portion of the solar collector assembly of FIG. 25a.

FIG. 24 is a diagram illustrating the heat transfer scheme incorporating solar collectors and a thermal ceiling construction as aforementioned;

FIG. 25 is a sectional view through a portion of a building and roof structure illustrating a modified heat transfer scheme;

FIG. 26 is a sectional view through A-A of FIG. 25;

FIG. 27 is a schematic view illustrating the interconnection of the components of the heat transfer scheme of FIG. 25; and

FIG. 28 is a schematic view of a solar air-conditioning system.

### DESCRIPTION OF EMBODIMENTS OF THE INVENTION

In this description, the use of like numerals represents like parts. In particular, the prime symbol (′) is used to indicate different forms of the same part.

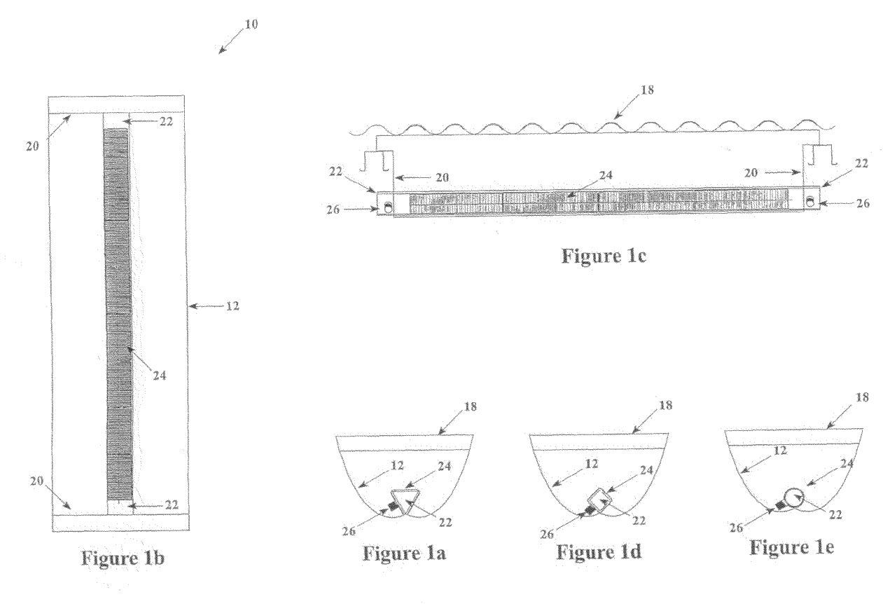

FIG. 1 illustrates the form of a solar collector unit 10 which comprises a shaped solar concentrator surface 12 which is provided with a transparent or translucent cover in the form of laminated glass 18. The translucent cover may be in the form of corrugated polycarbonate or PVC/Acrylic translucent sheeting which may include Fresnel lenses.

The solar concentrator surface 12 is elongate with a uniform cross-section in the shape of a compound parabola, namely two parabolas that share a common or substantially common focus. The concentrator surface may be constructed from metal or plastic sheet with a specular inner surface which may be formed by a coating. The ends are closed off by stop ends 20 as can be seen in FIG. 1b. It is understood that the specific profile of the solar concentrator surface will increase the amount of sunlight by up to 73% compared to the sunlight that could be harvested from a flat reflector surface of the same surface area.

As mentioned above, the parabolic concentrator surfaces share a common or substantially common focus. At this common focus is disposed an energy converter 22 which is triangular in cross-section but could also be square as shown as FIG. 1d or round as shown in FIG. 1e. The energy converter 22 is a hollow elongate body. Each triangular face has a bank 24 of photovoltaic cells mounted thereto. The photovoltaic cells are laminated to the faces of the energy converter 22. At the ends of the energy converter 22 are inlet and outlet ports 26 to allow fluid (preferably water) to flow through the energy converter. The body of the energy converter 22 is anodised upon completion of the manufacturing process to reduce electrical conductivity.

It will be appreciated that the energy converter 22 will heat up as a result of solar energy being impinged onto its faces. Thus it will be appreciated that the energy converter 22 serves a dual function by serving as a mount for photovoltaic cells as well as being a conduit for liquid passing therethough. The heat transfer to the liquid also serves to prevent overheating of the photovoltaic cells.

The photovoltaic cells can either be Sliver™ cells which are ultra thin, bifacial photovoltaic cells manufactured from monocrystalline silicon or standard silicone cells.

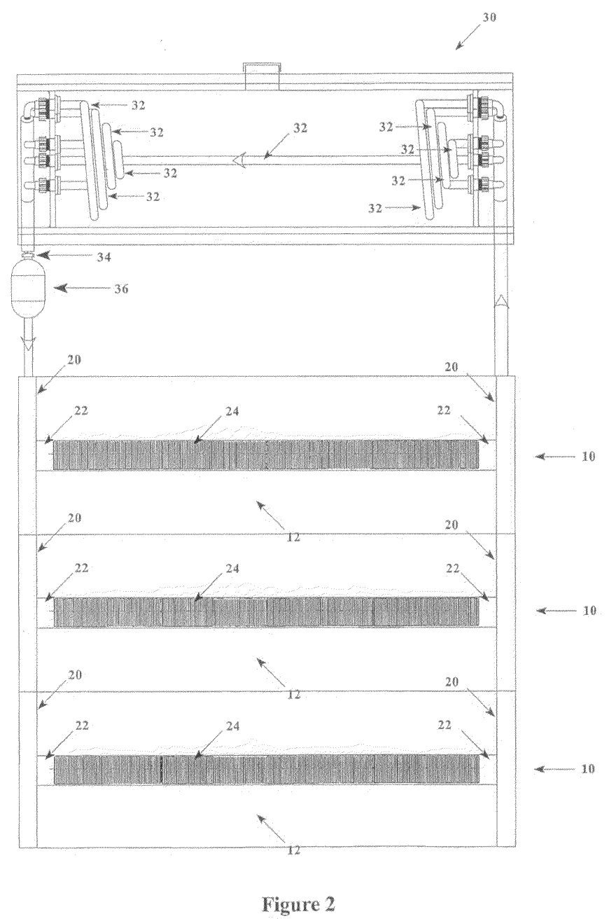

As shown in FIG. 2, a number of the solar collector units may be installed side by side and the water conduits interconnected so as to flow into a thermal storage vessel 30. Preferably, the liquid flowing through the energy converters 22 is water while the liquid within the thermal storage vessel 30 is calcium chloride (CaCl2 6H2O). Calcium chloride is a phase change material which has a melting point of 29° C. and releases 190 kj/kg of latent heat at the point of fusion. The water which has passed through the energy converters 22 is circulated through the thermal storage vessel 30 in a series of concentric spiral coils 32. Accordingly, heat collected by the water within the energy converters 22 is transferred to the calcium chloride within the vessel 30. The water then flows out of the vessel 30 through thermostat 34 and water circulating pump 36 and back through the solar collectors.

As shown, the solar collector assembly of FIG. 2 has three solar collectors. The assembly can fit between two adjacent roof trusses within a roof structure. The thermal storage vessel 30 ought to be located higher than the top of the solar collectors to facilitate thermo siphonic action. The thermostat 34 controls the water pump 36 which is a variable speed pump to circulate water through the system to ensure that the temperature of the photovoltaic cells does not exceed 30° C. This improves the efficiency of the photovoltaic cells since it is understood that the efficiency of such cells diminishes in proportion to the increase in temperature once they reach 30° C. It will be appreciated that the solar collectors 10 could instead be oriented at right angles to the thermal storage vessel 30. Any number and size of collectors 10 could be used.

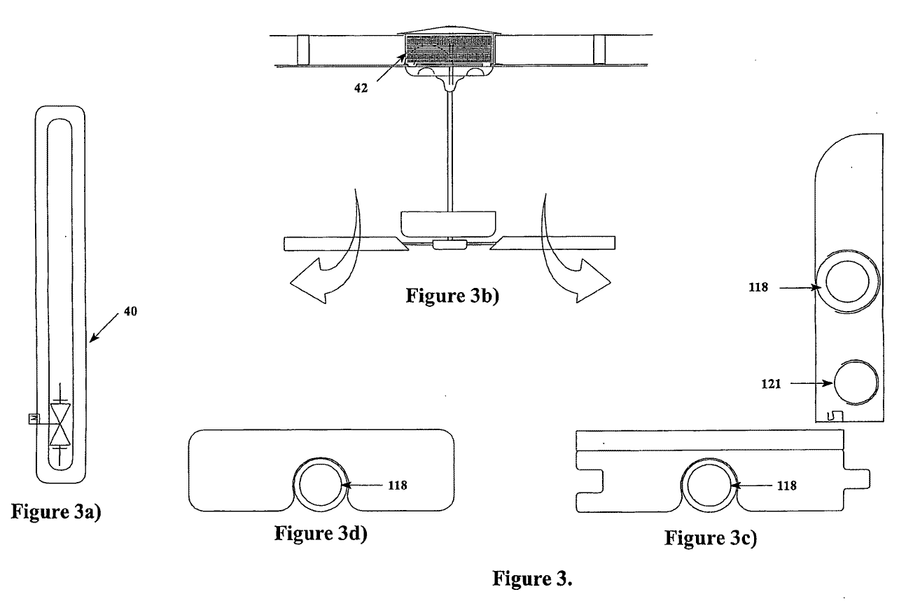

The heat collected by the thermal storage tank 30 can be used to perform a variety of functions including the provision of preheated water for a gas boosted domestic hot water unit. Alternatively, the water may be circulated through a variety of heat exchanger devices to heat space within the building. FIG. 3 contains a number of examples of such heat exchanger devices including a wall hung radiator 40 (FIG. 3a) which is filled with calcium chloride. FIG. 3b illustrates a ceiling fan having a mounting base 42 which is filled with calcium chloride.

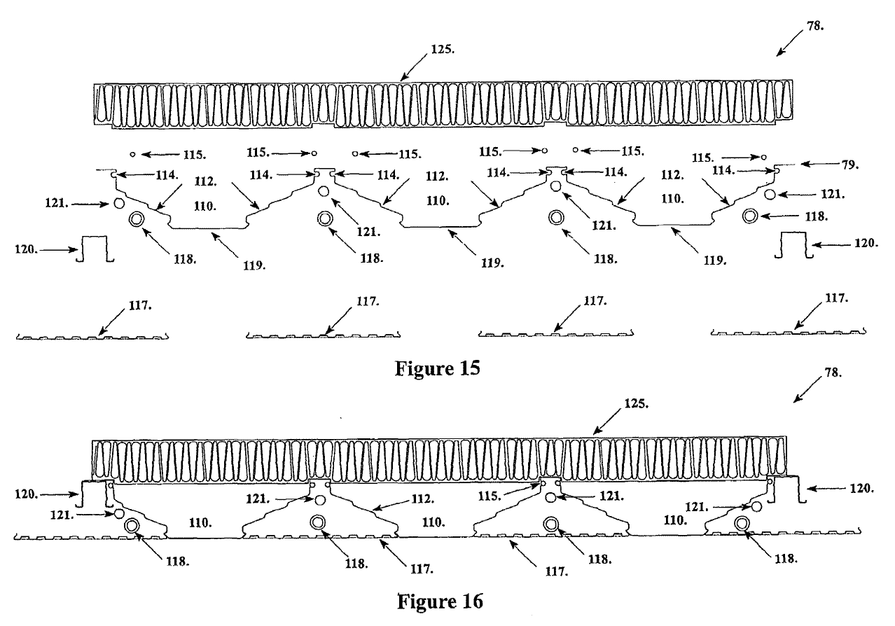

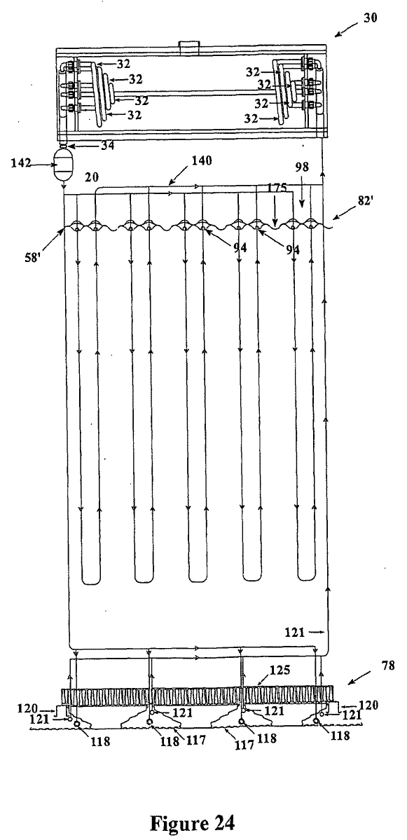

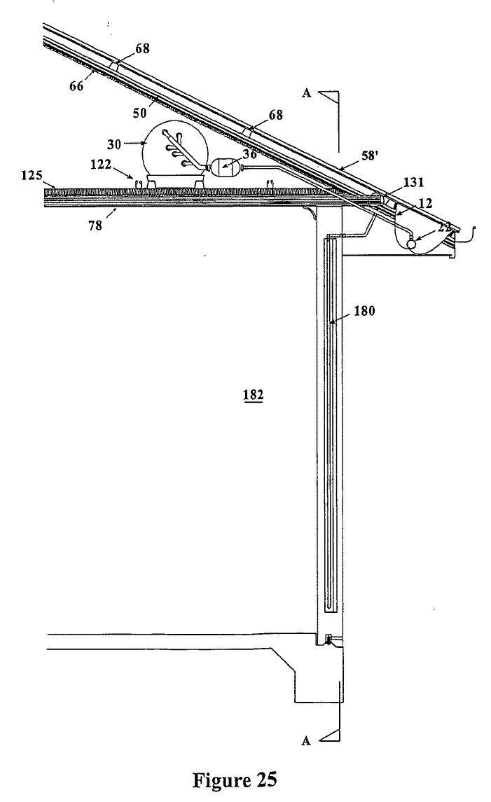

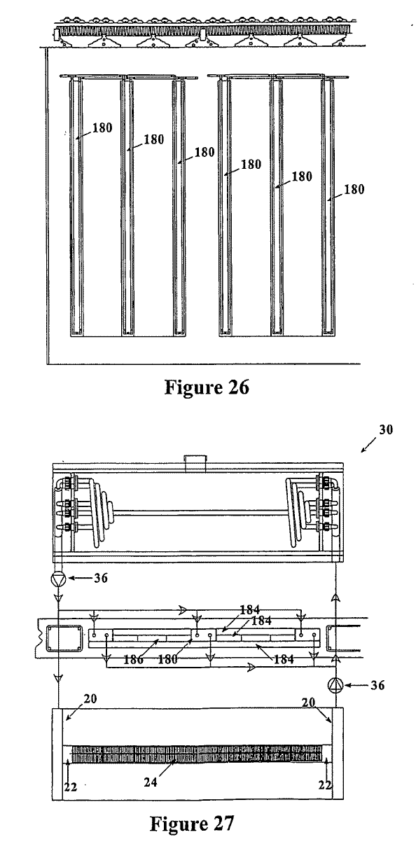

FIG. 3c illustrates flooring and skirting panels incorporating twin walled pipes 118 and return pipes 121 to circulate the heated water to thereby heat the space within the building. The twin walled pipes and return pipes 121 are described in connection with FIGS. 15 and 16. FIG. 3d is a small sealed plastic tank containing calcium chloride that can be attached to the upper surface of hydronic heating coils cast into a concrete slab to extend the heating cycle. See also the wall heating inserts shown in FIGS. 25 to 27. In these embodiments of FIGS. 3c, 3d, 15, 16, 24 to 27, the water pipes are routed through the heat exchanger devices, for heating the devices at night. This is explained best in connection with FIG. 24.

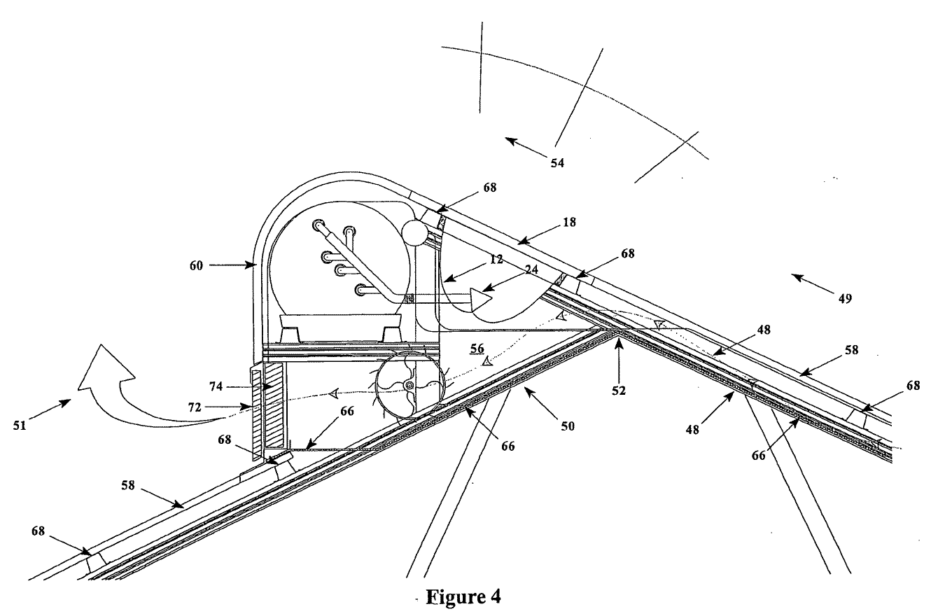

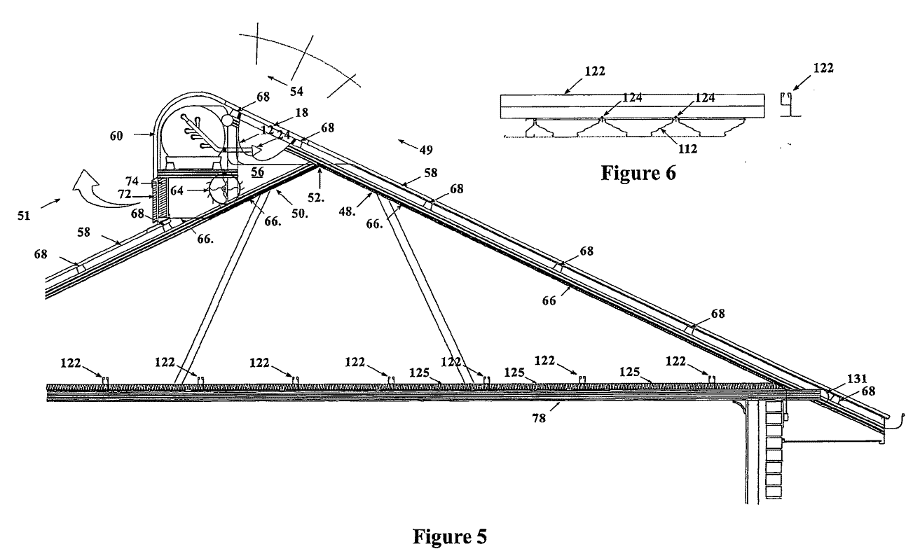

FIGS. 4 and 5 illustrate the solar collector assembly 10 of FIG. 1 installed within a roof space. The roof construction includes a number of spaced trusses, each of which is made up of a first top chord 48 and a second top chord 50. Each of the top chords 48 from the spaced trusses defines a first roofing plane 49 and each of the top chords 50 from the spaced trusses defines a second roofing plane 51. The roofing planes 49 and 51 intersect at point 52. However, top chord 48 is extended beyond the point of intersection to define an extended roofing plane 54 which defines a cavity 56 therebeneath. The solar collector assembly is housed within the cavity 56 with the transparent cover 18 extending in the extended roofing plane 54. A bull nosed cover 60 extends from the end of the transparent cover 18 in the extended roofing plane towards the second roofing plane 51.

The solar collector assembly is installed so that the longitudinal axis of the solar collector surface extends at right angles to the sun's azimuth at midday on the March and September equinox as diagrammatically depicted in FIGS. 4 and 5.

The first roofing plane 49 and second roofing plane 51 suitably support roof cladding 58 which may comprise conventional tiles or sheeting material.

The illustrated roof construction can be constructed as new or alternatively retrofitted into the roof of an existing home. To achieve this, the roof cladding is removed at the top of the second roofing plane 51. The top chord 48 of the trusses is extended to define the extended roofing plane.

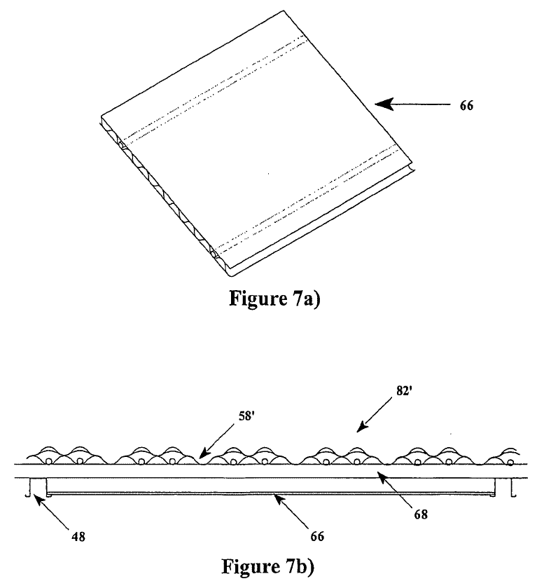

The embodiment of FIGS. 5 and 6 incorporates Corflute sheeting 66 which comprises a corrugated sheet bound between two planar sheets as shown in FIG. 7. The Corflute sheeting 66 can be manufactured from cardboard or plastic and may incorporate wire reinforcement to prevent sagging. The Corflute sheeting may also be laminated with aluminium foil to reflect heat and repel moisture. The sheeting may be laminated on one or both sides.

Purlins 68 extend transversely to the top chords 50 and are installed to span the top chords 48, 50 and support the roof cladding 58. The purlins 68 illustrated in FIG. 5. are of a top hat section.

The Corflute sheeting rests on a protruding lip located on the underside of the top chords 48 thereby facilitating airflow between the Corflute sheeting 66 and the roof cladding 58 as shown in FIGS. 4 and 7b). The airflow in the direction indicated by the arrows extends underneath the solar collector assembly 10′ and out through a hinged ventilation panel 72. The hinged ventilation panel 72 is mounted for pivotal motion at the edge of the bull nose cover 60 to thereby allow the exit of heated air. The airflow may be aided by cylindrical fan 64. The heated air may pass through a heat sink radiator 74 before exiting. FIGS. 5 and 6 also illustrates the arrangement of a thermal ceiling construction 78 which will be described further in conjunction with FIGS. 15 and 16.

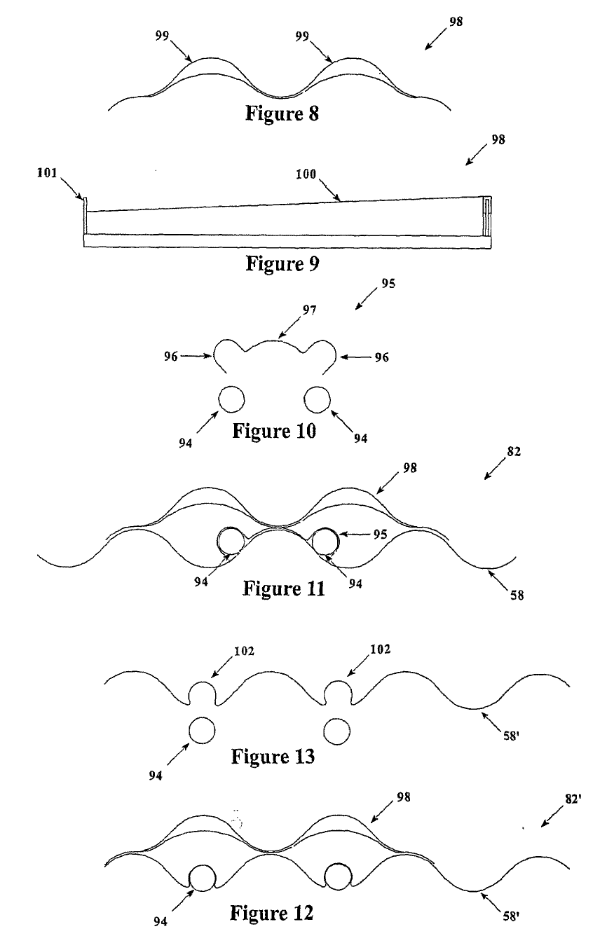

FIGS. 8 to 11 illustrate a modified form of a solar collector assembly 82. The solar collector assembly 82 is constructed by incorporating the roof cladding material 58 which is corrugated metal sheeting. A pair of conduit portions 94 is mounted in respective adjacent troughs of the corrugated sheeting 58. The conduits 94 may be black polyethylene pipe. The conduit portions 94 are encased in pressed metal jackets 95. As shown in FIG. 10, the pressed metal jackets 95 have first and second recesses 96 which are sized to receive the conduit portions 94. A bridging portion 97 extends between the two mounting portions 96. The pressed metal jackets 95 may be an elongate extruded section which may continue for the length of the conduit portions 94. The disposition of the mounting portions 96 is such that the conduit portions 94 will be spaced at an intermediate height between the troughs and peaks of the corrugated sheeting 58. Retaining the conduit portions 94 above the troughs means that the conduit portions 94 will not reside in any condensation collected in the troughs. In an alternative embodiment, discrete reflector portions (not shown) may be overlaid onto the roof cladding 58 with the conduits 94 and the pressed metal jackets 95 received on the reflector portions.

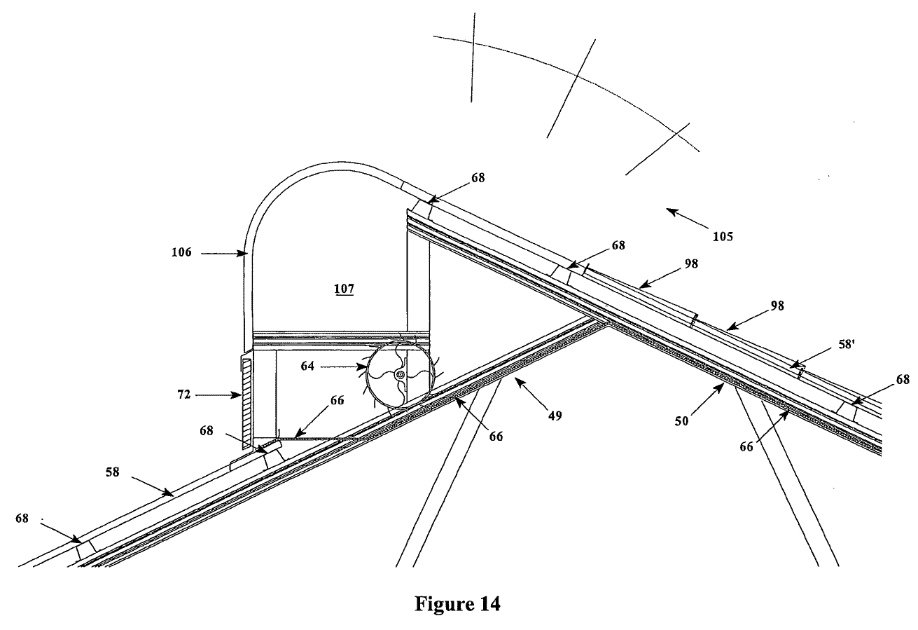

The solar collector assembly 82 is completed with a transparent cover 98 which is of the form shown in FIGS. 8 and 9. The transparent cover 98 is elongate with twin domes 99. The length of the cover 98 is intended to approximate the length of a typical roofing tile and has a sloping upper surface 100 inclined from one end towards a projecting ledge 101. This facilitates the overlapping of the covers 98 in the manner of roofing tiles as can be appreciated from a study of FIG. 14.

FIGS. 12 and 13 illustrate a modified form of a solar collector assembly 82′. In this embodiment, the roof cladding material 58′ is generally corrugated except that in the region where the troughs would have been, mounting portions 102 are integrally formed in the roof sheeting material 58′. These mounting portions 102 can receive the conduit portions 94. The transparent cover 98 is assembled over the top.

It will be understood that the conduit portions 94 are intended to convey water through the solar collector assemblies 82, 82′ for reticulation to and from a thermal storage vessel.

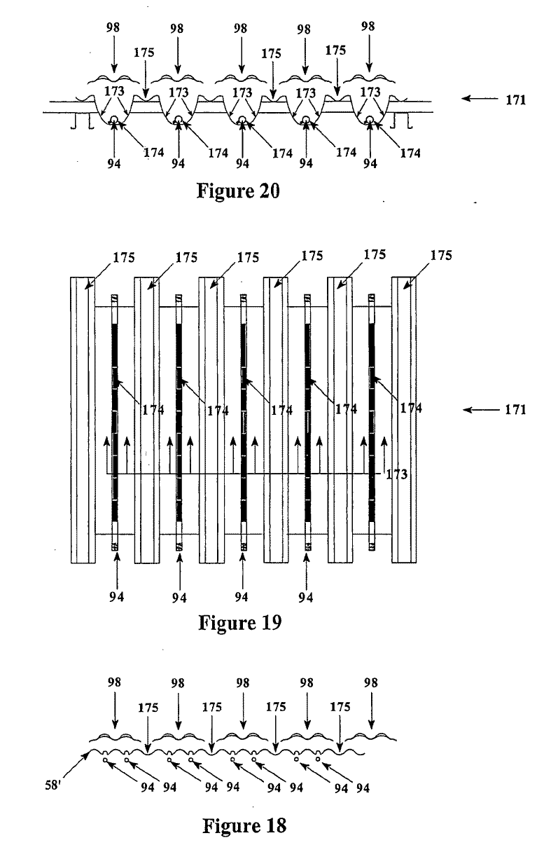

FIG. 18 is an exploded end view of the modified roof cladding 58′ which can be used in conjunction with multiple pairs of conduits 94 and a corresponding number of transparent covers 98. The intervening troughs 175 in the roof cladding 58 allow for drainage of water. An entire roof may be clad in the modified sheeting 58′.

FIG. 14 illustrates an alternative roofing construction where the northerly roof plane 105 is provided with solar collector assemblies 82′ mounted atop the roof sheeting 58′. The roof construction includes spaced trusses with top chords 49, 50. In this embodiment, the top chord 50 extends past the top chord 49. Purlins 68 support the roof sheeting 58′ atop the top chord 50 and the top chord 49. A plenum chamber 107 is created through the use of a bull nosed sheet 106 which extends along the ridge of the roof construction. The bull nosed sheet 106 is as explained in connection with FIGS. 4 and 5. A mechanically operated vent 72 is provided for the egress of heated air. As before, an air passage is created between the Corflute sheeting 66 and the roof sheeting 58 which flows into the plenum chamber 107 and out the vent 72. The vent may remain closed during cooler seasons so that air which is heated on the northerly aspect of the roof may be circulated through selected rooms of the building.

FIG. 15 is an exploded view of a thermal ceiling assembly 78. The ceiling assembly 78 comprises a unitary sheet 79 having longitudinally extending troughs 110 formed therein which alternate with shaped portions 112. The shaped portions 112 are shaped to increase the surface area and hence the heat transfer capabilities thereof. Furthermore, the shaped portions 112 may include longitudinally extending recesses 114 on either side near the apex of the shaped portions 112. The recesses 114 house perforated tubes 115 of a liquid dispersal network. The perforated tubes 115 allow water to trickle down the sides of the shaped portions 112 which together with airflow through the troughs 110 assists with cooling of the building space. Furthermore, the upper surface of the unitary sheet may be laminated with absorbent material such as paper or hessian to assist with water absorption. From FIG. 15, it can be seen that the ceiling construction also includes cover portions 117 to extend across the shaped portions 112. The troughs are defined by a planar region 119 at the base thereof which together with the covers 117 presents a substantially flat ceiling surface to the room. The covers 117 are in the form of pressed metal convection strips which are perforated to assist with heat transfer. Housed between each of the covers 117 and the shaped portions 112 is a series of heat exchange pipes 118, 121 which convey a heat transfer medium to thereby heat the space. The heat exchange pipes include four twin walled pipes 118 and four return pipes 121. The twin walled pipes 118 convey water within their inner wall. Between the inner wall and the outer wall, the twin walled pipes 118 store calcium chloride. In use, water is conveyed along the twin walled pipe 118 within one recess and is returned along return pipe 121 in another recess. The heated water thus heats the calcium chloride for subsequent heat dispersal.

The thermal ceiling sheet 79 is installed between the bottom chords 120 of adjacent roof trusses as shown in FIG. 16. The longitudinal edges of the sheeting 79 rest on top of the bottom chords 120. Metal sections 122 as shown in FIGS. 5, 6 and 17 also extend between the adjacent bottom chords 120, although this is not depicted in FIG. 20. As can be seen from the detail in FIG. 6, the peaks of the shaped portions 112 of the sheet 79 are connected to the metal sections 122 by threaded screws 124. The metal sections 122 also support the sheets of rigid insulation 125. The metal sections 122 also incorporate cable trays to support cables within the ceiling space. The metal sections 122 also enable personnel to walk within the roof space.

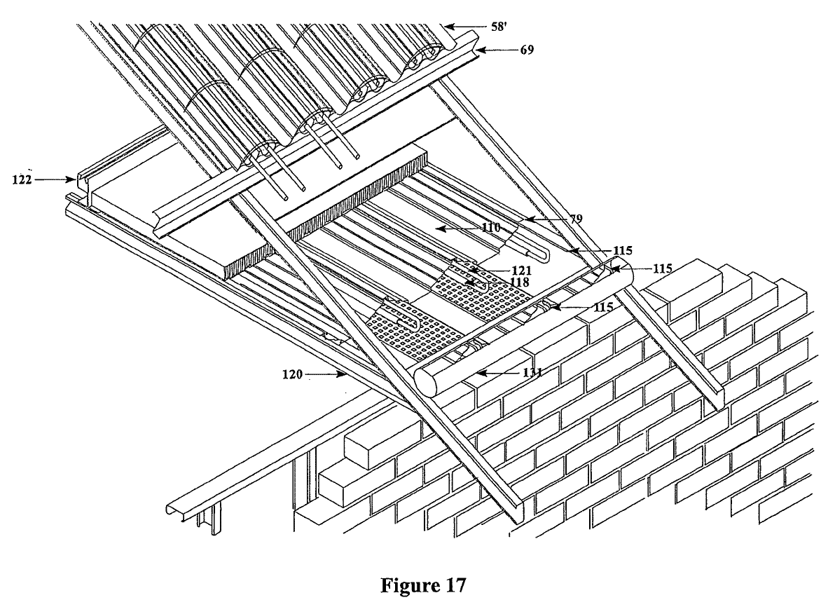

From a study of FIGS. 5 and 17, it would be appreciated that water expressed from the perforated tubes 115 within the troughs 110 will be evaporated as air flows through the troughs 110. This airflow will then flow through the air passage provided between the Corflute sheeting 66 and the roof sheeting 58 to then flow out through the ventilation panel 72 as has already been described. By virtue of the solar collector assembly 10 there may be particular heat build up in the air beneath which exits through the vent 72, thereby creating a venturi effect to draw air through the remainder of the air passages. Additionally, cylindrical fans 64 may be utilised to create appropriate airflow.

FIG. 17 is a cut away perspective view illustrating the main components of the construction. It is pointed out that the bottom chords 120 of the roof trusses are inclined to create a hydraulic grade to drain water within the troughs 110 towards a pump chamber 131 located on the outer face of the building above the eaves as shown.

The pump chamber 131 is frusto-cylindrical and is manufactured out of polyethylene pipe. The pump chamber is the same width as the ceiling sheet 79 or can be continuous across a number of ceiling panels.

A scavenger pump (not shown) which is fitted in the bottom of the chamber 131 is connected to a manifold that supplies water to the perforated tubes 115 located in recesses in the longitudinal troughs 110 of the ceiling sheeting 79. Alternatively, the water may be provided directly from the potable mains.

Multiple chambers 131 may be spaced along the edge of the building and the chambers may be connected together. As shown in FIG. 17, the ends of the heating pipes 118, 121 are connected together.

FIG. 19 shows in plan view, the form of a solar collection unit 171 which is a modular unit. The unit 171 as shown as FIG. 19 and FIG. 20 is made up of transparent covers 98 and reflector sheeting 173 having a specular surface. The specular surface 173 focuses the sunlight onto conduit 94 provided at the base of each trough in the sheeting. Additionally, between adjacent reflector troughs are provided rainwater troughs 175 to assist with conveying rainwater down the roof surface. The solar collector unit 171 may be installed in conjunction with standard roof cladding 58. Typically, the unit 171 may be utilised on an upper portion of the roof surface e.g. in the extended plane 54 of FIGS. 4 and 5 while the arrangement shown in FIG. 18 could be used on the remainder of the roof surface e.g. in the plane 49.

FIG. 21 illustrates another solar collector assembly with a modified form of internal conduit 94′. The internal conduit 94′ includes an outer tube 170 of clear plastic with an inner tube 172 of black polyethylene.

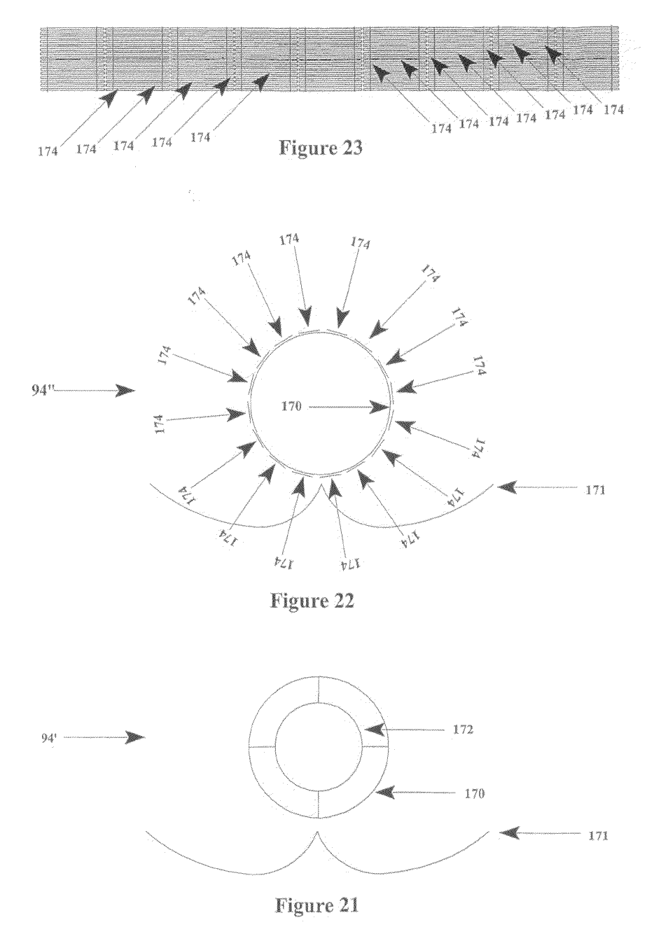

FIG. 22 illustrates another modified internal conduit 94″. In this embodiment, the internal conduit 94″ is comprised of a clear plastic pipe 170 which has Sliver™ cells 174 laminated to the outer surface. These Sliver cells are ultra thin, bifacial photovoltaic cells manufactured from monocrystalline silicon.

FIG. 23 shows in greater detail a typical flat assembly arrangement of the Sliver cells, which are then wrapped around and laminated onto the outer surface of the clear plastic tube 170.

FIG. 24 is a diagram illustrating the heating scheme whereby solar energy is harvested using the solar collector assemblies 82′ as shown in FIGS. 12, 13 and 18. Water flows through a pipe network 140 through the use of pump 142. Water which is heated in the solar collector assemblies 82′ is conveyed to the storage tank 30 which is filled with calcium chloride. The water is conveyed in a series of concentric coils 32 of plastic pipe through the storage vessel 30 and consequently, the heat which has been collected by the water is transferred to the calcium chloride within the storage vessel 30. The water is circulated through the solar collector assemblies 82′ and the thermal storage vessel 30 during daylight hours. As the sun sets and the temperature drops, the water is instead directed through the twin walled heating pipes 118 which contain calcium chloride. The heat is then dispersed to the calcium chloride within the twin walled heating pipes. The water is returned through the return pipes 121. Accordingly, the space within the room below the ceiling construction 78 will be heated by this method.

On the other hand, when the sun is out, the sun's energy can be utilised if heating is required within the building. As already explained in connection with FIGS. 4 and 5, an air space is created between the Corflute sheeting 66 and the roof sheeting 58 which will be heated by the sun's rays. With the vent 72 shown in FIGS. 4 and 5 closed, the cylindrical fan 64 can circulate warm air through the longitudinal troughs 110 of the ceiling construction 78. On the other hand, if the temperature rises beyond a certain point, the vent 72 will be opened and the airflow will exit through the vent. Additionally, the perforated tubes 115 within the ceiling construction 78 will disperse water over the ceiling sheeting 79 for evaporative cooling.

FIG. 25 illustrates a modified heat transfer scheme similar conceptually to the scheme of FIG. 24. However, in FIG. 25, one or more solar collector assemblies 10 are provided in the eaves of the building as shown. In this way, the solar collector assembly 10 can be easily incorporated into an existing building structure without needing to open up the roof or scale any great heights to install. If there are a number of solar collector assemblies these may be arranged end on end along the length of the eave. The solar collector assemblies 12 have internal conduits 22 which convey water therethrough which are fluidly connected to the thermal storage tank 30. Additionally, the thermal storage tanks 30 are connected to wall heating inserts 180. Thus, water which is heated in the solar collector assemblies 12 will be conveyed to the storage tank 30 to heat the calcium chloride within the storage vessel 30. As the sun sets and the temperature drops, the water instead will be directed through the wall heating inserts 180 to heat the internal space 182 of the room. This is depicted diagrammatically in FIG. 27.

The wall heating inserts 180 comprise plastic inserts which contain calcium chloride phase change material. The plastic inserts have internal water conduits for circulation of the water heated in the storage vessel 30. The inserts may be approximately 100 mm×50 mm in cross-section. The inserts may be cast into the wall panel material.

The inserts may be surrounded by thermal insulation such as sheets of polystyrene 184 to prevent heat loss to the exterior of the building. Service ducts 186 are provided for plumbing and electrical cables.

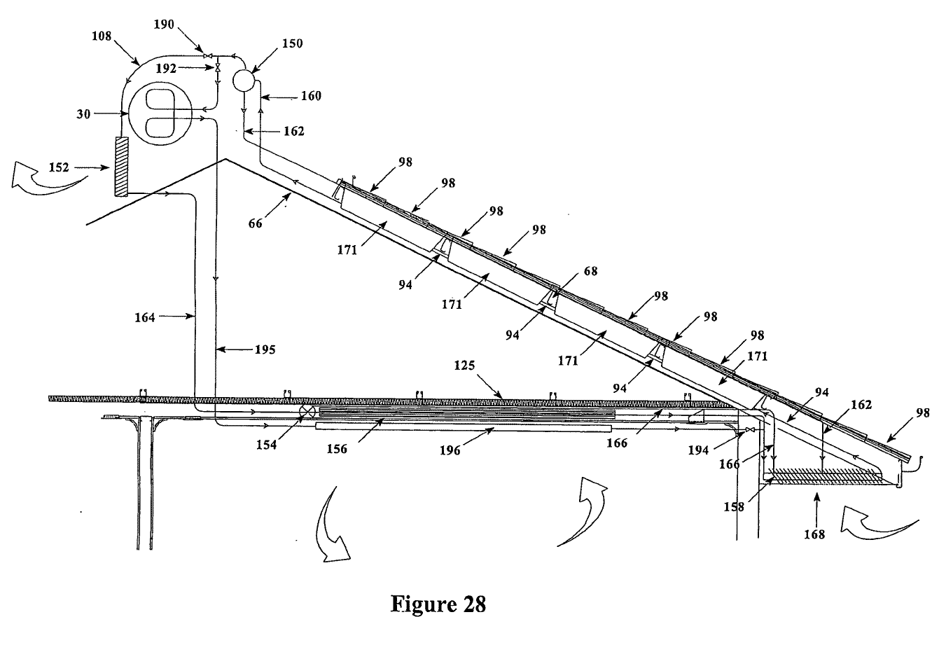

FIG. 28 illustrates the form of an air cooling/heating system which utilises many of the features described in the aforementioned embodiments. In particular, the roofing construction may be such that it includes a series of spaced trusses. In between a pair of spaced trusses is arranged a series of solar collection units 171 of the type shown in FIGS. 19 and 20. However, the solar collector assemblies may be any of the types disclosed above. The solar collector assemblies, instead of circulating water, form the basis of a solar generator in an absorption refrigeration system. This refrigeration system includes the components of the solar generator, as just mentioned, a separator 150, a condenser 152, an expansion valve 154, an indoor heat exchanger 156 (evaporator) and absorber 158. The basic operating elements of an absorption refrigeration system will be well known to those in the art of refrigeration. The system uses a refrigerant of a combination of water, ammonia and hydrogen gas to create a continuous cycle for the ammonia. The refrigerant passes through the internal pipes 94 in the solar generator. Solar heat raises the temperature of the refrigerant to the boiling point of the ammonia. The boiling solution then flows to the separator 150 through the percolator tube 160. In the separator 150, the water separates from the ammonia gas. The water is permitted to flow back along the liquid absorbent drain 162 back into the absorber. The ammonia gas in the separator 150 is subsequently forced by the pressure of the incoming fluid to the condenser via valve 190 which is open, valve 192 being closed. The condenser 152 is cooled by the air stream which flows out the mechanically operated vent 72 similar to that described in the embodiments of FIGS. 4, 5, 9, 14 and 18. The condenser 152 may be in the form of a heat exchanger which allows the ammonia gas to dissipate its heat and condense into a liquid. The liquid ammonia makes its way along the liquid ammonia drain 164 where it mixes with hydrogen gas at the expansion valve 154 and evaporates, taking latent heat from the air in contact with the outer surfaces of the evaporator 156 to produce a cooling effect within the room below. The ammonia and hydrogen gas then flow to the absorber 158. (Valve 194 is closed) Here, the water that has collected in the separator is mixed with the ammonia and hydrogen gases. The absorber 158 sits over perforated sheeting 168 which thereby defines an air intake vent to cool the absorber 158. The ammonia forms a solution with the water and releases the hydrogen gas which flows back to the evaporator along the hydrogen gas return line 166.

The foregoing describes the cooling mode of the system. The system enables the operator to select either heating or cooling mode. Upon selection of the heating mode, valves 192 and 194 are opened and valve 190 is closed creating a by-pass route for the heated ammonia gas which circulates through the thermal storage tank 30 to heat the phase change calcium chloride within the tank. The ammonia gas is then directed along line 195 to a network of twin walled pipes 196 within the ceiling to dissipate the heat to the building space. The twin walled pipes 196 may be of a similar construction to twin walled pipes 118 shown in FIGS. 15 and 16 with an outer layer containing calcium chloride. The ammonia gas travels through the core of the twin walled pipes 196 and then through valve 194, back to the absorber 158.

The foregoing describes only one embodiment of the present invention and modifications may be made thereto without departing from the scope of the present invention.

1.-68. (canceled)

69. A solar collector system including:
a photovoltaic means for conversion of solar energy into electrical energy; and a pathway for thermal transfer fluid which is in thermal communication with the photovoltaic means.

70. A solar collector system as claimed in claim 69 wherein the pathway comprises a conduit for the flow of the thermal transfer fluid and the system further includes a thermal storage vessel, wherein a fluid circulates through the conduit and the heat from the circulated fluid is transferred to a thermal storage medium disposed within the thermal storage vessel for subsequent dispersal.

71. A solar collector system as claimed in claim 69 wherein the pathway comprises a pipe and ultra thin mono-crystalline cells are arranged in spaced disposition on the surface of the pipe.

72. A solar collector system as claimed in claim 71 wherein the pipe is transparent to permit sunlight to permeate through the cells through to the pipe.

73. A solar collector system as claimed in claim 72 wherein the cells are bifacial.

74. A solar collector comprising:
a shaped solar concentrator surface having at least one focus; and a solar energy converter disposed at the focus of the shaped collector, wherein the solar energy converter is in the form of a vessel for thermal transfer fluid with a series of photovoltaic cells provided on the surface of the vessel.

75. The solar collector as claimed in claim 74 wherein there are a plurality of surface portions which are joined to form a compound surface and the surface portions have a common foci.

76. The solar collector as claimed in claim 75 wherein the vessel comprises an elongate conduit of uniform triangular cross-section with photovoltaic means provided on each of the three sides with two of the sides of the triangular cross-section oriented towards a respective surface portion.

77. The solar collector as claimed in claim 74 wherein the concentrator surface is elongate with a substantially uniform cross section and a linear focus along which the solar energy converter is disposed.

78. The solar collector as claimed in claim 74 wherein ultra thin mono-crystalline cells are arranged in spaced disposition on a pipe which extends at the focus at the solar concentrator.

79. The solar collector as claimed in claim 78 wherein the pipe is transparent to permit sunlight to permeate through the cells through to the pipe.

80. The solar collector as claimed in claim 79 wherein the cells are bifacial.

81. The solar collector as claimed in claim 74 wherein a fluid circulates through the vessel and the heat from the circulated fluid is transferred to a thermal storage medium disposed within a thermal storage vessel for subsequent dispersal.

82. A solar collector system including the solar collector as claimed in claim 74, the system further including a thermal storage vessel wherein a fluid circulates through the solar energy converter vessel and the heat from the circulated fluid is transferred to a thermal storage medium disposed within the thermal storage vessel.

83. A roofing structure comprising:
a first roofing plane supporting roof cladding material; a second roofing plane supporting roof cladding material with said first and second planes intersecting and wherein said first roofing plane extends beyond the intersection to define an extended roofing plane with a cavity therebeneath housing one or more components of a solar collector assembly.

84. The roofing structure as claimed in claim 83 wherein the solar collector system includes: a photovoltaic means for conversion of solar energy into electrical energy; and a vessel for thermal transfer fluid which is in thermal communication with the photovoltaic means.

85. The roofing structure as claimed in claim 83 wherein the solar collector assembly comprises: a shaped solar concentrator surface having at least one focus; and a solar energy converter disposed at the focus of the shaped collector, wherein the solar energy converter is in the form of a vessel for thermal transfer fluid with a series of photovoltaic cells provided on the surface of the vessel.

86. The roofing structure as claimed in claim 85 wherein the system further includes a thermal storage vessel, wherein a fluid circulates through the solar energy converter vessel and the heat from the circulated fluid is transferred to a thermal storage medium disposed within the thermal storage vessel.

87. The roofing structure as claimed in claim 83 wherein the solar collector assembly forms part of a solar space cooling or heating assembly.

88. The roofing structure as claimed in claim 83 wherein the extended roofing plane is supported by extension of one of the chords of a truss structure or by an extension of the beams on one side of a roof structure comprised of intersecting beams.

89. The roofing structure as claimed in claim 83 wherein the cavity is provided with a ventilation hatch for the release of trapped heated air from within the cavity or within the roof space.

90. A method of retrofitting one or more components of a solar collector assembly into a pitched roof structure comprised of first and second intersecting roofing planes supporting roof cladding material, said method including:
extending the first roofing plane beyond the point of intersection to define an extended roofing plane with a cavity therebeneath; and
installing a one or more components of the solar collector assembly within the cavity.

91. The method of claim 90 further including removing a top portion of roofing material from the second roofing plane.

92. A solar collector assembly comprising:
a reflector portion; and
a vessel disposed to receive reflected solar radiation from the reflector portion;
wherein the reflector portion provides an integrally formed mount for supporting the vessel.

93. The solar collector assembly as claimed in claim 92 wherein the reflector portion comprises sheeting having a shaped cross-section and the vessel is in the form of a conduit, the cross-section of the sheeting including an integrally formed trough to receive the conduit.

94. The solar collector assembly as claimed in claim 93 wherein the vessel is clear plastic tubing for the passage of water.

95. A solar collector assembly comprising:
a first reflector portion shaped to be received in a trough of corrugated roof cladding;
a conduit portion disposed to receive solar radiation from the first reflector portion; and
a cover extending over the first reflector portion and the conduit portion.

96. The solar collector assembly as claimed in claim 95 wherein a second reflector portion is also provided which is arranged to be received in an adjacent trough of the corrugated roof cladding, the second reflector portion being integrally formed with the first reflector portion.

97. The solar collector assembly as claimed in claim 96 further including a cover to extends over the first and second reflector portions to form a solar collector assembly.

98. A solar collector assembly comprising:
a first reflector portion; and
an internal conduit portion disposed to receive reflected solar radiation from the reflector portion, wherein the internal conduit portion is transparent or at least translucent.

99. The solar collector assembly as claimed in claim 98 wherein the internal conduit portion is provided with a plurality of ultra thin mono-crystalline cells arranged in spaced disposition on the surface and the cells are bifacial.

100. A roofing construction for a sloping or pitched roof, the roofing construction including solar collectors which incorporate one or more transparent or translucent domed covers, the domed covers having an axis of curvature which substantially aligns with the roof gradient.

101. The roofing construction as claimed in claim 100 wherein the covers are transversely spaced on the roof.

102. The roofing construction as claimed in claim 100 wherein there are a plurality of covers Which are nestable in a direction which substantially aligns with the roof gradient.

103. The roofing construction as claimed in claim 100 wherein the covers extend substantially the distance between the ridge and the eaves.

104. The roofing construction as claimed in claim 103 wherein each cover has a stepped outer surface to present an overlap appearance in the manner of roof tiles.

105. The roofing construction as claimed in claim 100 wherein the roofing construction includes corrugated roof sheeting having spaced troughs, the covers spanning transversely across two troughs of the sheeting with the solar collector defined within the two troughs.

106. The roofing construction as claimed in claim 105 wherein the corrugated sheeting forms a reflector portion of the solar collector.

107. A building construction including:
a sheeting product installed in a ceiling or a sub-roof space; and
a network for liquid dispersal onto the upper surface of the sheeting product, wherein the construction provides for evaporative airflow over the upper surface of the sheeting product.

108. The building construction as claimed in claim 107 wherein the sheeting product is shaped to present recesses for collecting of the liquid therein for subsequent evaporation.

109. The building construction as claimed in claim 107 wherein the sheeting product is laminated with absorbent material for improved dispersion of the liquid.

110. The building construction as claimed in claim 107 wherein the sheeting product is shaped to increase the surface area and accordingly the heat transfer capabilities thereof.

111. The building construction as claimed in claim 107 wherein the construction provides for an airflow path along the sheeting product to be vented externally of the building construction.

112. The building construction as claimed in claim 111 wherein the building construction incorporates a solar collector, and the airflow path passes along the underside of the, solar collector.

113. A ceiling construction including:
a sheeting product having one or more recesses defined therein to house thermal transfer pipes; and
one or more covers to extend across the respective recesses.

114. The ceiling constructions as claimed in claim 113 wherein the sheeting product is shaped to increase the surface area and accordingly the heat transfer capabilities thereof.

115. The ceiling constructions as claimed in claim 113 wherein the construction provides for an airflow path along the sheeting product to be vented externally of the construction.

116. An assembly for a ceiling within a room or space, the assembly including:
a sheeting product, including a shaped portion to increase the surface area and hence the heat transfer capabilities thereof and one or more planar portions adjacent to the shaped portion;
cooling and/or heating components disposed on or adjacent the sheeting product; and
a cover portion to extend across the shaped portion to present, towards the room, a substantially planar ceiling surface.

117. An assembly for a ceiling as claimed in claim 116 wherein the sheeting product is shaped to present recesses for collecting of liquid therein for subsequent evaporation.

118. The assembly as claimed in claim 116 wherein the sheeting product is laminated with absorbent material for improved dispersion of the liquid.

119. The assembly as claimed in claim 116 wherein the construction provides for an airflow path along the sheeting product to be vented externally of the building construction.

120. A solar cooling system comprising:
a solar collector to heat a liquid passing therethrough by solar radiation;
means for circulating a solution of an evaporable refrigerant in a less evaporable solvent through said solar collector; and
an absorption refrigeration system, wherein the solar collector serves as a vapour generator of said system, the system further including a vapour liquid separator connected to an outlet of said solar collector, a condenser for condensation of a heated vapour of said refrigerant, an expansion valve through which the condensed refrigerant is introduced into an indoor heat exchanger for heat exchange between the refrigerant and air and an absorber in which the cooled refrigerant is absorbed in said solvent, wherein the solar collector is arranged on a roof surface, the subspace of the roof surface being vented to enhance air flow underneath the solar collector, and wherein said condenser and/or the absorber is arranged to be cooled by the vented air flow.

121. The solar cooling system as claimed in claim 120 wherein the absorber is disposed in the eaves of the building construction in the region of an air intake vent.

122. The solar cooling system as claimed in claim 120 wherein the condenser is disposed in the region of an air outlet vent.

123. The solar cooling system as claimed in claim 120 wherein the solar cooling system is operable on reverse cycle by reversing the operations of the indoor heat exchanger and the condenser.

124. A solar heating/cooling system for heating or cooling a building space comprising:
a solar collector adapted to heat a solution of an evaporable refrigerant in a less evaporable solvent through said solar collector;
a heating/cooling regime selection means for selective operation of the system for either a heating or cooling mode;
an absorption refrigeration system operable on selection of cooling mode, wherein the solar collector serves as a vapour generator of said system, the system further including a vapour liquid separator connected to an outlet of said solar collector, a condenser for condensation of a heated vapour of said refrigerant, an expansion valve through which the condensed refrigerant is introduced into an indoor heat exchanger for heat exchange between the refrigerant and air and an absorber in which the cooled refrigerant is absorbed in said solvent; and
a thermal storage and dispersal system operable on selection of heating mode, wherein the thermal storage and dispersal system includes a thermal storage vessel operable for circulation of the solar heated refrigerant therethrough for subsequent dispersion of the heat to the building space.

125. The solar heating/cooling system as claimed in claim 124 wherein, in the heating mode, the outlet of the vapour liquid separator is diverted from the condenser, through the thermal storage and dispersal system.

126. The solar heating/cooling system as claimed in claim 124 where the heating/cooling regime selection means facilitates manual selection.

127. The solar heating/cooling system as claimed in claim 124 where the heating/cooling regime selection means includes a thermostat to facilitate automatic selection.

128. A building construction including:
a heating assembly comprising a first conduit for circulating heating fluid and a second conduit or vessel housing the first conduit, wherein a thermal storage material is provided between the first conduit and the second conduit or vessel; and
a wall, the heating assembly being disposed within the wall.

129. The building construction of claim 128 wherein the thermal storage material is calcium chloride.

130. The building construction of claim 128 wherein the wall is a cast panel and the heating assembly is cast into the wall panel material.

131. The building construction of claim 128 wherein the second conduit or vessel is a conduit.

132. A building component including:
a heating assembly comprising a first conduit for circulating heating fluid and a second conduit or vessel housing the first conduit, wherein a thermal storage material is provided between first and second conduit or vessel.

133. The building component of claim 132 wherein the building component is a wall.

134. The building component of claim 133 wherein the wall is a precast panel construction.

135. The building component of claim 132 wherein the building component is a flooring panel.

136. The building component of claim 132 wherein the building component is a skirting panel.
